(19) United States
(12) Patent Application Publication
(10) Pub. No.: US 2015/0273537 A1
(43) Pub. Date: Oct. 1, 2015

(54) SUBSTRATE CLEANING METHOD AND SUBSTRATE CLEANING APPARATUS

(71) Applicant: SCREEN Holdings Co., Ltd., Kyoto (JP)

(72) Inventor: Katsuhiko MIYA, Kyoto (JP)

(21) Appl. No.: 14/592,058

(22) Filed: Jan. 8, 2015

(30) Foreign Application Priority Data
Mar. 26, 2014 (JP) 2014-063861

(51) Int. Cl. B08B 3/12; H01L 21/02

(52) U.S. Cl. CPC B08B 3/12; H01L 21/02057

(57) ABSTRACT

A method includes: a liquid film forming step of supplying first liquid to a first major surface of the substrate and forming a first liquid film; and a cleaning step of a cleaning step of cleaning the second major surface by providing the second major surface of the substrate with ultrasonic wave-applied liquid, which is obtained by applying ultrasonic waves to second liquid, in a condition that the first liquid film is formed on the first major surface. The first liquid has a lower cavitation intensity than the cavitation intensity of the second liquid, the cavitation intensity being stress per unit area which acts upon the substrate due to cavitations which are created during propagation of ultrasonic waves to liquid.

### CROSS REFERENCE TO RELATED APPLICATION

The disclosure of Japanese Patent Applications enumerated below including specification, drawings and claims is incorporated herein by reference in its entirety:

No. 2014-063861 filed Mar. 26, 2014.

### BACKGROUND OF THE INVENTION

1. Field of the Invention

The present invention relates to a method of and an apparatus for cleaning a substrate that has a first major surface on which a pattern is formed and a second major surface to be cleaned. The substrate may be a semiconductor wafer, a glass substrate for photo mask, a glass substrate for liquid crystal display, a glass substrate for plasma display, a substrate for FED (Field Emission Display), a substrate for optical disc, a substrate for magnetic disk and a substrate for magneto-optical disk among others.

2. Description of the Related Art

During manufacturing electronic components such as semiconductor devices and liquid crystal display devices, a step of processing such as film forming processing and etching of a front surface of a substrate is repeated to thereby form a micro-pattern. If there is a particle adhering to the back surface of the substrate, the particle causes defocusing at a photolithographic step and makes it difficult to form a desirable micro-pattern. Further, the substrate whose back surface carries the particle may give rise to cross contamination. It is also to be noted that vacuum sucking of the back surface of the substrate is often performed for transporting the substrate, during which phase a particle may adhere to the back surface of the substrate. For this reason, a great number of techniques for cleaning a substrate at the back surface of the substrate have been proposed. For instance, the apparatus according to JP-A-2010-27816 supplies ultrasonic processing liquid, which is obtained by applying ultrasonic waves to processing liquid, to the back surface of a substrate and realizes ultrasonic cleaning. In an effort to prevent transmission of ultrasonic waves to the front surface of the substrate and damage upon a pattern formed in the front surface of the substrate during ultrasonic cleaning, this apparatus forms a film of the liquid in the front surface of the substrate, freezes the liquid film and accordingly reinforces the pattern.

### SUMMARY OF THE INVENTION

However, in the case of the apparatus according to JPA-2010-27816, it is necessary to first freeze the liquid film for preventing damage upon the pattern and thereafter clean the back surface of the substrate. This requires a long total time for cleaning the back surface of the substrate, i.e., a long tact time. Further, cooling gas needs be supplied to the liquid film for the purpose of the freezing processing, and therefore, an increase of a running cost is inevitable.

The invention was made in light of the problem described above, and therefore, an object of the invention is to provide a substrate cleaning method and a substrate cleaning apparatus with which it is possible to favorably clean a second major surface of a substrate while suppressing damage upon a pattern which is formed in a first major surface of the substrate without increasing the tact time or the running cost.

According to a first aspect of the disclosure, there is provided a substrate cleaning method of cleaning a substrate that has a first major surface on which a pattern is formed and a second major surface to be cleaned/ The method comprises: a liquid film forming step of supplying first liquid to the first major surface of the substrate so as to form a first liquid film with the first liquid; and a cleaning step of cleaning the second major surface by providing the second major surface of the substrate with ultrasonic wave-applied liquid, which is obtained by applying ultrasonic waves to second liquid, in a condition that the first liquid film is formed on the first major surface, wherein the first liquid has a lower cavitation intensity than the cavitation intensity of the second liquid, the cavitation intensity being stress per unit area which acts upon the substrate due to cavitations which are created during propagation of ultrasonic waves to liquid.

According to a second aspect of the disclosure, there is provided a substrate cleaning apparatus for cleaning a substrate that has a first major surface on which a pattern is formed and a second major surface to be cleaned. The apparatus comprises: a liquid film former that supplies first liquid to the first major surface of the substrate so as to form a first liquid film with the first liquid; a nozzle that ejects second liquid toward the second major surface of the substrate in the condition that the first liquid film is formed on the first major surface; a vibrator that is disposed to the nozzle; and an oscillator that outputs an oscillation signal to the vibrator and makes the vibrator apply ultrasonic waves to the second liquid, wherein the liquid film former uses, as the first liquid, liquid which has a lower cavitation intensity than the cavitation intensity of the second liquid, the cavitation intensity being stress per unit area which acts upon the substrate due to cavitations which are created during propagation of ultrasonic waves to liquid.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a drawing which shows a first embodiment of a substrate cleaning apparatus according to the invention.

FIG. 2 is a partial plan view of the apparatus shown in FIG. 1.

FIG. 3 is a timing chart of the oscillation signal.

FIG. 4 is a flow chart which shows the operations performed by the substrate cleaning apparatus shown in FIG. 1.

FIG. 5 is a schematic drawing which shows the operations performed by the substrate cleaning apparatus shown in FIG. 1.

FIGS. 6A through 6C are drawings which show the experiments for verifying the relationship between the oscillation signal and the capability of cleaning and the results of the experiments.

### DETAILED DESCRIPTION OF THE PREFERRED EMBODIMENTS

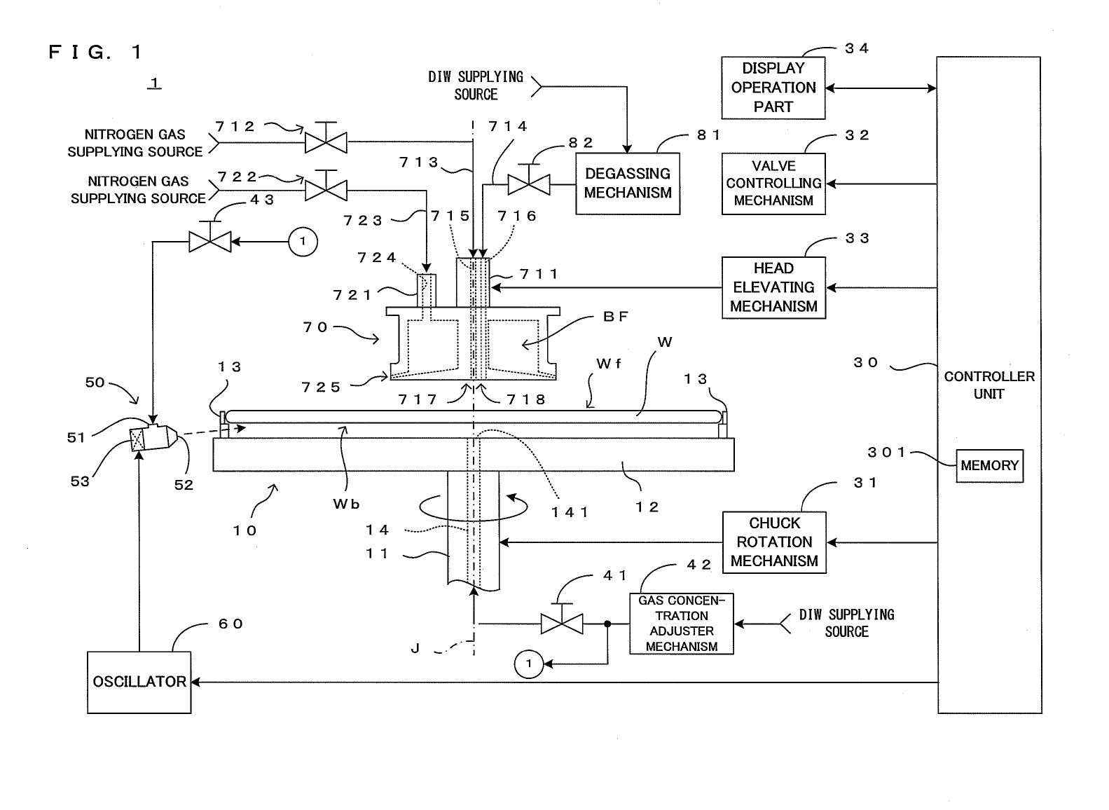

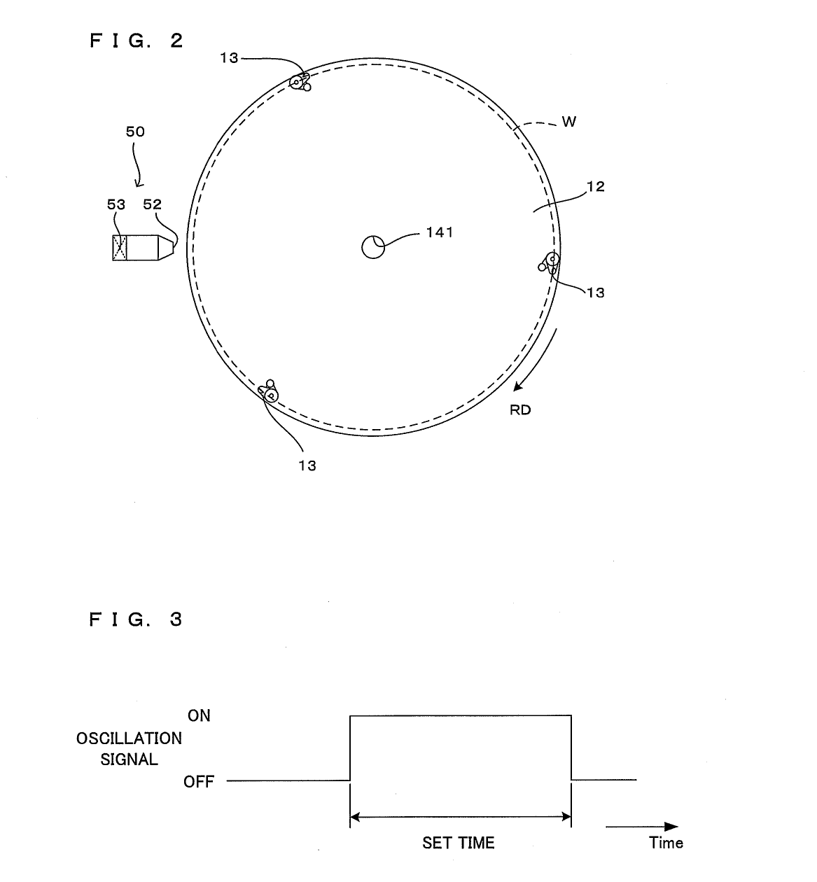

FIG. 1 is a drawing which shows a first embodiment of a substrate cleaning apparatus according to the invention. FIG. 2 is a partial plan view of the apparatus shown in FIG. 1. The substrate cleaning apparatus 1 is an apparatus which removes unwanted matters such as particles adhering to the back surface Wb of a substrate W which may be a semiconductor wafer or the like using ultrasonic wave-applied liquid which is obtained by applying ultrasonic waves to liquid, while holding the substrate W in a face-up state that the front surface Wf of the substrate W is directed toward above. Describing specifically, DIW (De Ionized Water) is used as the liquid mentioned above in this apparatus, and this apparatus spin-dries the substrate W which is wet with DIW after cleaning of the back surface of the substrate with pulse-like ultrasonic wave-applied liquid, which is obtained by intermittently applying ultrasonic waves to DIW, supplied to the back surface Wb of the substrate W. Although not shown in the drawings, a device pattern made of poly silicon and the like is formed in the front surface Wf of the substrate W.

The substrate cleaning apparatus 1 comprises a spin chuck 10 which holds the substrate W approximately horizontally and rotates the substrate W in a condition that the front surface Wf of the substrate W is directed toward above. A rotary spindle 11 of the spin chuck 10 is linked with a rotary spindle of a chuck rotation mechanism 31 which includes a motor so that as the chuck rotation mechanism 31 is driven, the spin chuck 10 can rotate about a rotation axis J (vertical axis). A disk-shaped spin base 12 is connected and integrated with the top edge of the rotary spindle 11 using a fastening part such as a screw. Therefore, as the chuck rotation mechanism 31 operates in response to an operation command given from a controller unit 30 which controls the entire apparatus, the spin base 12 rotates about the rotation axis J. The controller unit 30 controls the chuck rotation mechanism 31 and accordingly adjusts the number of revolutions.

A plurality of chuck pins 13 for holding the substrate W at the periphery are disposed upright in the vicinity of the peripheral edge of the spin base 12. More than one chuck pins 13 may be provided to securely hold the disk-like substrate W, and along the peripheral edge of the spin base 12, the chuck pins 13 are disposed at equal anglular intervals about the center of rotation of the substrate W (the rotation axis J). According to this embodiment, there are three chuck pins 13 as shown in FIG. 2.

Each chuck pin 13 comprises a substrate supporter section for supporting the peripheral edge of the substrate W from below and a substrate holder section for pressing the exterior peripheral edge surface of the substrate W supported by the substrate supporter section and accordingly holding the substrate W. Each chuck pin 13 is structured so as to be able to switch between the pressing state in which it presses the exterior peripheral edge surface of the substrate W and the release state in which it is off and away from the exterior peripheral edge surface of the substrate W.

The plurality of chuck pins 13 are released when the substrate W is handed over to the spin base 12 but remain in the pressing state for cleaning of the substrate W. When in the pressing state, the plurality of chuck pins 13 can hold the substrate W at the peripheral edge of the substrate and keep the substrate W approximately horizontally at a position above the spin base 12 over a predetermined gap from the spin base 12. In this manner, the substrate W is supported in the face-up state that the front surface (pattern seating surface) Wf of the substrate W is directed toward above and the back surface Wb is directed toward below.

As the chuck rotation mechanism 31 drives and rotates the spin chuck 10 which thus holds the substrate W, DIW is supplied to a central area of the back surface Wb of the substrate W from below the substrate W, to a peripheral edge area of the back surface Wb of the substrate W from outside the substrate W via the space between the spin base 12 and the substrate W, and to a central area of the front surface Wf of the substrate W from above the substrate W, and cleaning is achieved.

In this embodiment, the rotary spindle 11 has a hollow shape and a DIW supply pipe 14 is inserted through the hollow section of the rotary spindle 11. The DIW supply pipe 14 extends even to the top surface of the spin base 12, and the edge surface of the DIW supply pipe 14 is faced with the central area of the back surface Wb of the substrate W. In short, a top edge section of the DIW supply pipe 14 functions as a nozzle hole 141. Meanwhile, a bottom edge section of the DIW supply pipe 14 is connected with a DIW source via a valve 41 and a gas concentration adjuster mechanism 42. The DIW source may be utility which is available in a plant where the apparatus 1 is installed. Of course, a DIW storage tank may be disposed within the apparatus 1 and used as the DIW source.

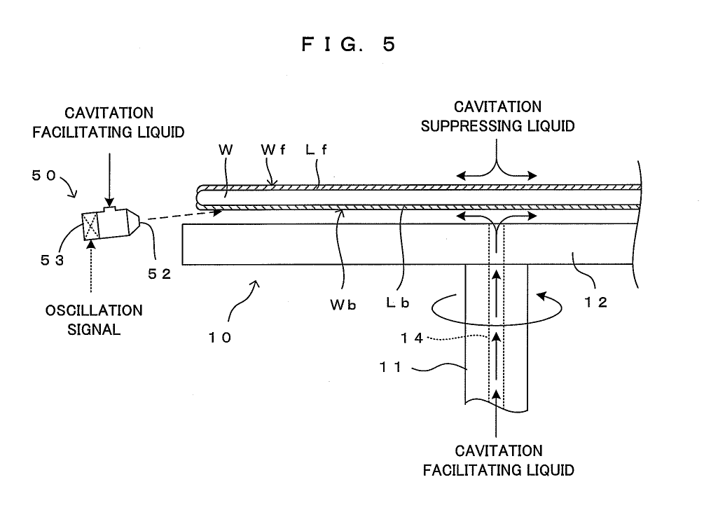

The gas concentration adjuster mechanism 42 has a function of dissolving nitrogen gas in DIW supplied from the DIW source, enhancing the gas concentration within DIW approximately to the saturation level and creating gas-rich DIW. The specific structure of the gas concentration adjuster mechanism 42 may be the one described in JP-A-2004-79990 for instance. The increase of the concentration of the dissolved gas in DIW in this manner facilitates generation and elimination of air bubbles caused by application of ultrasonic waves to DIW, namely, cavitation, and attains an excellent cleaning effect. To enhance the cleaning effect, gas-rich DIW (hereinafter referred to as “the cavitation facilitating liquid”) is created in this embodiment. As a valve controlling mechanism 32 instructs the valve 41 to open, the valve 41 opens and the DIW supply pipe 14 receives the cavitation facilitating liquid which is fed under pressure from the gas concentration adjuster mechanism 42. As a result, the cavitation facilitating liquid is discharged toward the central area of the back surface of the substrate W from the nozzle hole 141 which is disposed at the top edge section of the DIW supply pipe 14. On the other hand, when the valve 41 closes as instructed by the valve controlling mechanism 32, supply of the cavitation facilitating liquid toward the central area of the back surface of the substrate W is discontinued. In this embodiment, the cavitation facilitating liquid is discharged while rotating the substrate W as described later so that the cavitation facilitating liquid supplied to the back surface Wb of the substrate W spreads to the peripheral edge of the substrate W due to centrifugal force and a liquid film Lb of the cavitation facilitating liquid (FIG. 5) is formed.

The pipe which connects the gas concentration adjuster mechanism 42 with the valve 41, in its middle section, branches out as a different pipe and extends toward an ultrasonic wave nozzle 50 which is fixedly disposed outside the chuck pins 13 (on the left-hand side in FIG. 1) as shown in FIG. 1, and the tip end of this pipe is connected with an inlet 51 of the ultrasonic wave nozzle 50. A valve 43 is inserted into this branching pipe. Hence, when the valve controlling mechanism 32 instructs the valve 43 to open, the valve 43 opens, the ultrasonic wave nozzle 50 receives the cavitation facilitating liquid which is fed under pressure from the gas concentration adjuster mechanism 42 and the cavitation facilitating liquid is discharged from a discharge outlet 52 along the back surface Wb of the substrate W. Thus discharged cavitation facilitating liquid is supplied to the peripheral edge of the back surface Wb of the substrate W from outside the substrate W via the space between the spin base 12 and the substrate W. On the other hand, when the valve 43 closes as instructed by the valve controlling mechanism 32, pressurized feeding of the cavitation facilitating liquid to the ultrasonic wave nozzle 50 is discontinued and supply of the cavitation facilitating liquid is discontinued.

A vibrator 53 is disposed to the ultrasonic wave nozzle 50 so as to apply ultrasonic waves to the cavitation facilitating liquid. Describing in more detail, the vibrator 53 is disposed on the opposite side to the discharge outlet 52 along the direction in which the cavitation facilitating liquid is discharged from the discharge outlet 52, as shown in FIG. 1. When an oscillation signal is output to the vibrator 53 from an oscillator 60 in accordance with a control signal from the controlling unit 30, the vibrator 53 vibrates and ultrasonic waves are generated. In this embodiment, as shown in FIG. 3, receiving the control signal from the controlling unit 30, the oscillator 60 continuously provides a signal of a constant frequency to the vibrator 53 only for a period of time which is set in advance.

Further, this embodiment uses the following structure for the purpose of achieving a function of supplying DIW to the central area of the front surface Wf of the substrate W from above the substrate W and a function of supplying the gas toward the front surface of the substrate W. That is, a fluid ejection head 70 is disposed above an approximately central section of the front surface of the substrate. There are two fluid introducing units 711 and 721 which are disposed to the top of the fluid ejection head 70 such that the fluid introducing units 711 and 721 protrude upright toward above. Of these fluid introducing units, the fluid introducing unit 711 has a function of receiving nitrogen gas which is fed under pressure from a nitrogen gas source disposed outside and DIW which is fed under pressure from the DIW source. Meanwhile, the fluid introducing unit 721 only has a function of receiving nitrogen gas which is fed under pressure from a nitrogen gas source disposed outside. To be more specific, a pipe 713, which is connected with the external nitrogen gas source and in which a valve 712 is inserted, and a pipe 714, which is connected with the external DIW source and in which a degassing mechanism 81 and a valve 82 are inserted, are connected with the fluid introducing unit 711.

Inside the fluid introducing unit 711, two supply channels 715 and 716 are provided extending in the vertical direction. The bottom ends of the supply channels 715 and 716 are open toward the approximate center of the substrate W at the bottom surface (the surface opposed against the front surface Wf of the substrate W) of the fluid ejection head 70, and respectively function as a gas outlet 717 and a DIW outlet 718. The top ends of the supply channels 715 and 716 are linked respectively with the pipes 713 and 714. Hence, when the valve controlling mechanism 32 instructs the valve 712 to open, the valve 712 opens, the fluid ejection head 70 receives nitrogen gas which is supplied from the nitrogen gas source. When the valve controlling mechanism 32 instructs the valve 82 to open, the valve 82 opens, DIW supplied via the degassing mechanism 81 is fed into the fluid ejection head 70. On the other hand, as the valves 712 and 82 close as instructed by the valve controlling mechanism 32, supply of nitrogen gas and DIW is discontinued.

The degassing mechanism 81 is disposed according to this embodiment, for the purpose of removing the dissolved gas from DIW, i.e., execution of degassing to thereby reduce the concentration of the dissolved gas in DIW which is to be fed to the fluid ejection head 70, and therefore, it is possible to suppress cavitation in DIW. DIW as it is treated by degassing to decrease the cavitation intensity will now be referred to as “the cavitation suppressing liquid” the technical meaning of which will be described in detail later.

A pipe 723, which is connected with the nitrogen gas source and in which a valve 722 inserted, is connected with the other fluid introducing unit 721 which is disposed in the fluid ejection head 70. The valve 722 opens and closes under control of the valve controlling mechanism 32 which is controlled by the controlling unit 30. When the valve 722 opens as needed, nitrogen gas fed from the nitrogen gas source is guided into a buffer space BF which is created inside the fluid ejection head 70 via a gas supply channel 724. Further, a gas ejection outlet 725 linked to the buffer space BF is disposed to the side exterior periphery of the fluid ejection head 70.

As described above, this embodiment requires use of the two types of nitrogen gas supplying lines. In one of these lines which is comprised of the nitrogen gas source, the valve 712, the pipe 713 and the supply channel 715, nitrogen gas fed under pressure from the nitrogen gas source is discharged via the supply channel 715 toward the central area of the front surface of the substrate W from the gas outlet 717 which is disposed at the bottom surface of the fluid ejection head 70.

In the other one of the nitrogen supplying line which is comprised of the nitrogen gas source, the valve 722, the pipe 723 and the supply channel 724, nitrogen gas fed under pressure from the nitrogen gas source is fed into the buffer space BF created inside the fluid ejection head 70 and then ejected toward outside via the gas ejection outlet 725. At this stage, the nitrogen gas is extruded via the gas ejection outlet 725 which is shaped like a slit which extends approximately horizontally. Therefore, thus ejected nitrogen gas spreads in a restricted area along the vertical direction, but in the horizontal direction (the circumferential direction), spreads in an approximately isotropic manner. That is, as the nitrogen gas is gushed out from the gas ejection outlet 725, above the substrate W, an air flow like a thin layer is created which flows from an approximately central section of the substrate W toward the periphery of the substrate W. It is to be particularly noted that according to this embodiment, gas supplied under pressure is guided once into the buffer space BF and then jetted out via the gas ejection outlet 725, and therefore, a uniform quantity of ejection is achieved along the circumferential direction. In addition, as pressurized nitrogen gas is ejected through the small gap, the velocity of the gas flow increases and the nitrogen gas is gushed out vigorously. As a result, nitrogen gas flows are discharged from around the fluid ejection head 70, whereby foreign matters, mist and the like falling down toward the front surface Wf of the substrate W are blocked and a surrounding atmosphere is blocked from the front surface Wf of the substrate W.

The fluid ejection head 70 is held above the spin base 12 by an arm not shown, and the arm is connected with a head elevating mechanism 33 which is controlled by the controlling unit 30 such that the arm can freely ascend and descend. Due to this structure, the fluid ejection head 70 is set at an opposed position against the front surface Wf of the substrate W, which is held by the spin chuck 10, with a predetermined gap (which may for instance be approximately 2 to 10 mm) between the fluid ejection head 70 and the front surface Wf. The fluid ejection head 70, the spin chuck 10, the head elevating mechanism 33 and the chuck rotation mechanism 31 are housed inside a processing chamber (not shown).

Denoted at 34 in FIG. 1 is a display operation part which is formed by a touch panel and the like and which functions as both a display part for displaying image information fed from the controller unit 30 and an manipulation entering part for receiving information which a user enters by manipulating a key or button displayed on the display part and transmitting the information to the controller unit 30. Of course, the display part and the manipulation entering part may be disposed as separate parts. In addition, denoted at 301 in FIG. 1 is a memory which is disposed in the controller unit 30 and which has a function of storing various conditions set in advance for the cleaning processing, namely, a processing condition, a cleaning program, etc.

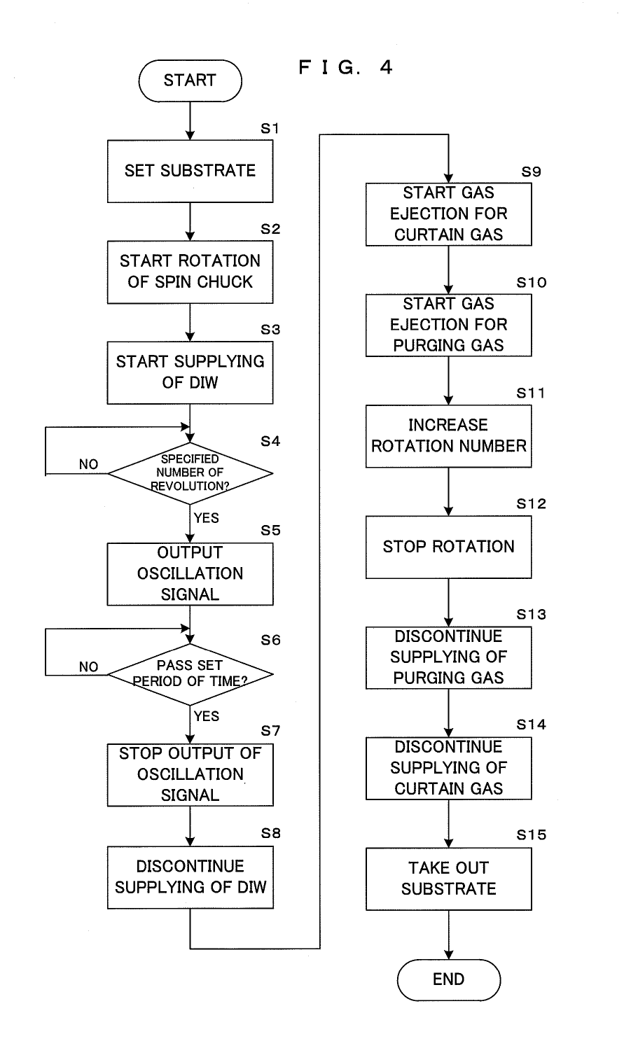

Operations of the apparatus will now be described with reference to FIGS. 3 through 5. FIG. 3 is a timing chart of the oscillation signal. FIG. 4 is a flow chart which shows the operations performed by the substrate cleaning apparatus shown in FIG. 1. FIG. 5 is a schematic drawing which shows the operations performed by the substrate cleaning apparatus shown in FIG. 1.

Prior to the start of the processing, the valves 41, 43, 82, 712 and 722 are all close and the spin chuck 10 is still. The controlling unit 30 controls the respective sections of the apparatus as described below in accordance with a program stored in advance in the memory 301, whereby the back surface of the substrate W is cleaned and dried. That is, a substrate transportation robot (not shown) sets one substrate W upon the spin chuck 10 and the chuck pins 13 hold the substrate W (Step S1). At this stage, although the fluid ejection head 70 may be driven by the head elevating mechanism 33 as needed and move to a retracted position above the spin chuck 10 so that the substrate would be smoothly loaded if this is necessary, as long as there is a sufficient distance between the substrate and the fluid ejection head 70, it is not necessary to move the fluid ejection head 70. This is true with unloading of the substrate as well which will be described later.

Next, the spin chuck 10 starts rotating at Step S2. In addition, supply of DIW to the substrate W is started (Step S3). Describing this in more detail, the valves 41 and 43 are opened and the cavitation facilitating liquid is ejected from the nozzle hole 141 and the discharge outlet 52 toward the back surface Wb of the substrate W. Further, the valve 82 is opened and cavitation suppressing liquid is ejected from the DIW outlet 718 toward the front surface Wf of the substrate W. In consequence, a liquid film Lf of the cavitation suppressing liquid is formed on the front surface Wf of the substrate W (liquid film creating step) as shown in FIG. 5.

As the spin chuck 10 then reaches a set number of revolutions which is specified in the program mentioned above (“YES” at Step S4), the oscillation signal is output to the vibrator 53 from the oscillator 60 (Step S5) as shown in FIG. 3. In this embodiment, the cavitation facilitating liquid which is obtained by continuously applying ultrasonic waves is supplied to the back surface Wb of the substrate W and the back surface is cleaned (cleaning step). This cleaning processing is continued only for a set period of time which is specified in the program mentioned above, and when the passage of the set period of time is confirmed at Step S6, the oscillator 60 stops outputting the oscillation signal (Step S7), the valves 41, 43 and 82 are closed and supply of the cavitation facilitating liquid (DIW) and the cavitation suppressing liquid (DIW) is discontinued (Step S8).

Completion of the cleaning processing is followed by drying processing for removing DIW which still remains on the front surface Wf and the back surface Wb of the substrate W. In other words, the valve 722 is opened while rotating the substrate W and ejection of nitrogen gas from the gas ejection outlet 725 disposed around the fluid ejection head 70 is started (Step S9). Following this, the valve 712 is opened, thereby starting supply of nitrogen gas toward the front surface Wf of the substrate W from the gas outlet 717 disposed at the bottom surface of the fluid ejection head 70 (Step S10).

The velocity of the nitrogen gas supplied through the gas ejection outlet 725 is fast and the direction in which the nitrogen gas is ejected is limited along the vertical direction, which creates a curtain of the nitrogen gas which flows above the substrate W radially toward the periphery of the substrate from the central area of the substrate. Meanwhile, the velocity of the nitrogen gas supplied through the gas outlet 717 is slower, and the flow rate of this nitrogen gas is restricted so that this nitrogen gas would not be strongly blown toward the front surface Wf of the substrate W. Hence, the nitrogen gas supplied through the gas outlet 717 acts so as to purge the air which remains in the space between the curtain-like layer of gas jetted out from the gas ejection outlet 725 and the front surface Wf of the substrate W and to maintain a nitrogen atmosphere within this space. Noting this, the nitrogen gas supplied through the gas ejection outlet 725 will now be referred to as “the curtain gas” and the nitrogen gas supplied through the gas outlet 717 will now be referred to as “the purging gas.”

In the condition that the curtain of gas is created above the substrate W and the front surface Wf of the substrate W is maintained in the nitrogen atmosphere, the number of revolutions at which the spin chuck 10 rotates is increased and the substrate W is rotated at a high speed (Step S11), and the substrate W is drained off of the pure water which remains on the front surface Wf and the back surface Wb of the substrate W and is dried. Supply of the curtain gas and the purging gas is continued during execution of the drying processing, thereby preventing adhesion of mist and the like to thus dried front surface Wf of the substrate W and oxidation. The spin chuck 10 stops rotating after the end of the drying processing (Step S12), and supply of the purging gas is discontinued, followed by discontinuation of supply of the curtain gas (Step S13 and Step S14). The substrate transportation robot then takes out the substrate W thus dried from the spin chuck 10 and transports the substrate W to other apparatus (Step S15), which completes cleaning of the back surface of one substrate W. As this processing is repeated, it is possible to sequentially process a plurality of substrates.

As described above, according to this embodiment, in the condition that the pattern is protected with the liquid film Lf of the cavitation suppressing liquid formed on the front surface (pattern seating surface) of the substrate W, the ultrasonic wave-applied liquid (the cavitation facilitating liquid+ultrasonic waves) is supplied to the back surface Wb of the substrate W and the back surface is cleaned, and therefore, it is possible to clean the back surface Wb of the substrate W in a favorable manner while suppressing damage upon the pattern. In short, for the purpose of ultrasonic cleaning of the back surface Wb, the cavitation facilitating liquid in which nitrogen gas has been dissolved approximately to the saturation level is used. Therefore, application of ultrasonic waves to the cavitation facilitating liquid gives rise to massive cavitation, which makes it possible to effectively clean the back surface Wb.

Since the cavitation facilitating liquid to which ultrasonic waves are applied is supplied such that the cavitation facilitating liquid would flow along the back surface Wb, sonic waves could be transmitted to the front surface Wf as well and accordingly damage the pattern. However, it is to be noted in this embodiment that the liquid film Lf is formed on the front surface Wf of the substrate W using the cavitation suppressing liquid which has a small cavitation intensity. That is, DIW is degassed before supplied to the front surface Wf so that the concentration of the dissolved gas becomes lower than that in the cavitation facilitating liquid. In this manner, the cavitation intensity of the liquid to be supplied to the front surface Wf of the substrate W, namely, the cavitation suppressing liquid is lowered. “The cavitation intensity” referred to in this context means the stress per unit area which cavitation caused by ultrasonic waves in the liquid makes act upon the substrate W. The cavitation intensity is determined by the coefficient of cavitation a and the bubble collapsing energy U. In other words, the coefficient of cavitation a is calculated by the formula below:

α=(Pe−Pv)/(ρV²/2) (Formula 1)

where Pe is indicative of the static pressure, Pv is indicative of the vapor pressure, ρ is indicative of the density and V is indicative of the flow velocity. The smaller the coefficient of cavitation α is, the greater the cavitation intensity becomes. Meanwhile, the bubble collapsing energy U is calculated by the formula below:

U=4πr² σ=16πσ³/(Pe−Pv)² (Formula 2)

where r is indicative of the radius of bubbles as they are before collapsing and σ is indicative of the surface tension. The greater the bubble collapsing energy U is, the greater the intensity of cavitation is.

According to this embodiment, since the concentration of the gas dissolved into the cavitation suppressing liquid by degassing is suppressed low, the vapor pressure Pv is significantly reduced. Hence, the coefficient of cavitation α increases while the bubble collapsing energy U decreases, which reduces the cavitation intensity of the cavitation suppressing liquid. As a result, although sonic waves are transmitted to the front surface Wf during the back surface cleaning processing, the cavitation intensity is suppressed low, and therefore, it is possible to effectively suppress destruction of the pattern on the front surface of the substrate.

Further, freezing which always needs be performed in the apparatus according to JP-A-2010-27816 is not necessary, which makes it possible to favorably clean the back surface Wb of the substrate W while discouraging damage upon the pattern without increasing the tact time or the running cost.

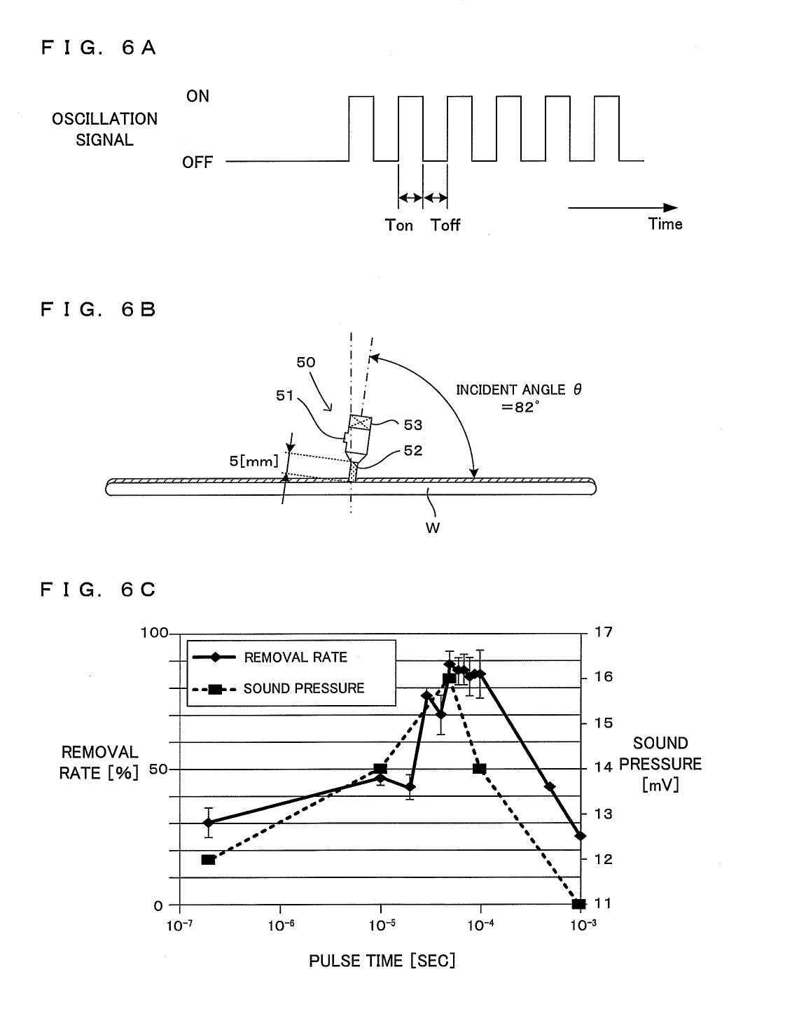

By the way, although the oscillator 60 continuously provides the vibrator 53 with the signal having the constant frequency for the period of time set in advance and the ultrasonic wave-applied liquid is consequently created inside the ultrasonic wave nozzle 50 according to the embodiment above, the oscillation signal is not limited to this. For instance, the oscillator 60 may output an oscillation signal in which an ON-signal for oscillating the vibrator 53 for a certain period of time (which has the time width Ton) and an OFF-signal for stopping the vibrator 53 from vibrating for a certain period of time (which has the time width Toff) are alternately switched over, so as to alternately apply and stop applying ultrasonic waves to the cavitation facilitating liquid, as shown in FIG. 6A. However, in the event that this oscillation signal is used, the capability of cleaning becomes different depending upon the time width Ton of the ON-signal. Noting this, which setting of the time widths Ton and Toff would be preferable for improvement of the capability of cleaning was verified. This will now be described with reference to FIGS. 6A through 6C.

FIGS. 6A through 6C are drawings which show the experiments for verifying the relationship between the oscillation signal and the capability of cleaning and the results of the experiments. One experiment which was conducted covered the removal rate (hereinafter “the experiment A”) and the other experiment which was conducted covered the sound pressure (hereinafter “the experiment B”).

The experiment A will be described first. As shown in FIG. 6B, a 300 [mm]-silicon wafer was prepared as the substrate W, and particles (Si scraps) were dispersed in advance on the front surface of the substrate W. After measuring the number of the particles within a measurement segment of 6×8 [square mm] in a central area of the front surface Wf of the substrate W, a liquid film of DIW was created on the front surface Wf of the substrate W. Following this, as shown in FIG. 6B, the ultrasonic wave nozzle 50 was disposed so that the discharge outlet 52 of the ultrasonic wave nozzle 50 would be 5 [mm] away from the front surface Wf of the substrate W in the direction which was at an angle θ (=82 degrees). While supplying DIW to the ultrasonic wave nozzle 50 at the flow rate of 1.5 [L/min], the oscillation signal containing the ON-signal having the frequency of 5 [MHz] was fed to the vibrator 53, ultrasonic waves were accordingly applied to DIW at 20 [W], and thus obtained ultrasonic wave-applied DIW was supplied to a central area of the front surface Wf of the substrate W for 30 seconds. After this, the number of the particles remaining in the measurement segment mentioned above in the front surface Wf was measured, and the removal rate of particles was calculated. Such an experiment was conducted while changing the time width Ton of the ON-signal and the time width Toff of the OFF-signal contained in the oscillation signal. In this experiment, the rate of the time width Ton to the time width Toff was set as (1:1). In other words, this experiment was conducted with the duty ratio of 50%, and in FIG. 6C, the pulse time [seconds] measured along the horizontal axis represents the time width Ton of the ON-signal as well as the time width Toff of the OFF-signal. The number of the particles was measured using a wafer inspection apparatus SP 1 manufactured by KLA-Tencor. Denoted at the solid line in FIG. 6C is indicative of the result of the experiment A described above, which result means the following. That is, the removal rate of particles becomes the maximum when the pulse time is approximately 5×10⁻⁵ through 10⁻⁴ [seconds] and becomes shorter when the pulse time is shorter or longer than this.

The experiment B will now be described. In the experiment B, while changing the time width Ton of the ON-signal as well as the time width Toff of the OFF-signal contained in the oscillation signal, the sound pressure inside DIW discharged from the discharge outlet 52 of the ultrasonic wave nozzle 50 was measured using a hydrophone. Denoted at the broken line in FIG. 6C is indicative of the result of the experiment B described above, which result means the following. That is, the sound pressure becomes the largest when the pulse time is approximately 5×10⁻⁵ [seconds] and becomes smaller when the pulse time is shorter or longer than this.

As comparison of the experiment A with the experiment B shows, the pulse time at which the removal rate of particles reaches the maximum is approximately equal to the pulse time at which the sound pressure becomes the maximum, and the rates at which the both decrease in accordance with changes of the pulse time are also similar to each other. Hence, with respect to the sound pressure of ultrasonic waves within the cavitation facilitating liquid ejected from the ultrasonic wave nozzle 50 inside the substrate cleaning apparatus 1, changes in response to the time width Ton of the ON-signal may be measured in advance and the time width Ton of the ON-signal may be set in accordance with the measurement result. Describing this more specifically, a peak time width over which the sound pressure reaches the peak may be calculated and the time width Ton of the ON-signal may be set to a value within a range which corresponds to the peak time width mentioned above or the full width at half maximum of the peak, thereby improving the removal rate of particles and enhancing the efficiency of cleaning of the back surface.

As described above, in the first embodiment, the front surface Wf and the back surface Wb of the substrate W correspond respectively to “the first major surface” and “the second major surface” of the invention, the degassing mechanism 81 and the fluid ejection head 70 function respectively as “the degasser” and “the ejector” of the invention which form “the liquid film former” of the invention. The cavitation suppressing liquid and the cavitation facilitating liquid correspond respectively to “the first liquid” and “the second liquid” of one example of the invention. Further, the liquid films Lf and Lb correspond respectively to “the first liquid film” and “the second liquid film” of one example of the invention.

The invention is not limited to the embodiment described above but may be modified in various manners in addition to the embodiments above, to the extent not deviating from the object of the invention. For instance, although the first embodiment above uses the cavitation facilitating liquid, namely, the liquid obtained by dissolving gas in DIW fed from the DIW source and increasing the concentration of the gas as “the second liquid,” DIW supplied from the DIW source may be used as it is (second embodiment). Alternatively, functional water such as carbonated water which is obtained by dissolving carbon dioxide gas in DIW and hydrogen water which is obtained by dissolving hydrogen gas in DIW may be used (third embodiment). In other words, even when liquid (DIW) of the same composition is used as “the first liquid” and “the second liquid” as in the first, the second and the third embodiments, as long as the gas concentration in “the first liquid” is set to be lower than that in “the second liquid,” the effect above is obtained. This is true not only with DIW but with general cleaning liquid which is generally used for cleaning of substrates, such as SC 1 (solution which is mixture of ammonium hydroxide and hydrogen peroxide) and liquid principal ingredients of which are isopropyl alcohol (IPA), ethanol and hydrofluoroether (HFE).

Further, liquid having different compositions may be used as “the first liquid” and “the second liquid” of the invention, and as the cavitation intensity of “the first liquid” is set to be lower than that of “the second liquid,” a similar effect to that according to the first embodiment is obtained. For example, although degassed DIW is used as the cavitation suppressing liquid (the first liquid) according to the first embodiment, this is not limiting: liquid having a smaller cavitation intensity than that of the ultrasonic wave-applied liquid ejected from the ultrasonic wave nozzle 50 may be used as the cavitation suppressing liquid. That is, it is preferable to use liquid which has a large coefficient of cavitation a and/or a smaller bubble collapsing energy U as the cavitation suppressing liquid. Where the coefficient of cavitation a and the bubble collapsing energy U of DIW take the value “1,” those of isopropyl alcohol, HFE7300 and HFE7100 are as described below. HFE7300 and HFE7100 respectively mean products which have the trade names of Novec (registered trademark) 7300 and Novec 7100 and are manufactured by 3M Japan.

TABLE 1

| | COEFFICIENT OF | BUBBLE COLLAPSING |
|---|---|---|
| LIQUID | CAVITATION α | ENERGY U |
| DIW | 1 | 1 |
| IPA | 1.2 | 0.03 |
| HFE7300 | 0.5 | 0.01 |
| HFE7100 | 0.6 | 0.01 |

For instance, isopropyl alcohol has a larger coefficient of cavitation a than that of DIW and a much smaller bubble collapsing energy U than that of DIW. Therefore, isopropyl alcohol or mixture of isopropyl alcohol and DIW can be preferably used as the cavitation suppressing liquid. Further, since isopropyl alcohol and the mixture solution above are each so-called low surface tension liquid, supplying any one of these two to the front surface Wf of the substrate W and forming the liquid film Lf there is desirable also for effective prevention of destroying of a pattern during drying.

In addition, according to the first embodiment, the cavitation facilitating liquid (the second liquid) is supplied to the central area of the back surface of the substrate W while rotating the substrate W, and in the condition that the liquid film Lb is present, the ultrasonic wave-applied liquid is supplied to the back surface Wb from outside the chuck pins 13 (i.e., the left-hand side in FIG. 5) along the radial direction of the substrate W as shown in FIG. 5. While this realizes propagation of ultrasonic waves to the entire back surface Wb and achieves cleaning of the back surface, the ultrasonic wave-applied liquid may be supplied to the central area of the back surface of the substrate W.

Further, although the gas concentration adjuster mechanism 42 dissolves nitrogen in DIW and the gas concentration in DIW is increased according to the first embodiment, other inactive gas or carbon dioxide gas may be used instead of using nitrogen gas.

According to the invention employing such a structure, the first liquid film is formed on a first major surface of the substrate, namely, the surface which seats the pattern, using the first liquid. The ultrasonic wave-applied liquid (the second liquid +ultrasonic waves) is supplied to the second major surface of the substrate so that the second major surface is accordingly cleaned while protecting the pattern with the first liquid film. At this stage, while ultrasonic waves are transmitted to the first major surface from the second major surface of the substrate, the cavitation intensity of the first liquid is set to be lower than that of the second liquid which is one ingredient of the ultrasonic-wave applied liquid. That is, while the cavitation intensity of the second liquid which is one ingredient of the ultrasonic-wave applied liquid is set to be relatively high, the cavitation intensity of the first liquid is set to be relatively low. The cavitation intensity is the stress per unit area which is created by propagation of ultrasonic waves and acts upon the substrate. Hence, large stress acts upon the second major surface of the substrate which receives the second liquid (ultrasonic wave-applied liquid) which has a relatively high cavitation intensity, whereby particles and the like adhering to the second major surface are removed and the second major surface is cleaned in a favorable manner. Meanwhile, even if ultrasonic waves are transmitted to the first major surface of the substrate which receives the first liquid which has a relatively low cavitation intensity, stress acting upon the first major surface is small and damage upon the pattern is therefore small.

According to the invention, with the first liquid whose cavitation intensity is lower than that of the second liquid, the first liquid film is formed on the first major surface of the substrate (pattern-seating surface), and the second major surface of the substrate is cleaned using the ultrasonic wave-applied liquid (the second liquid +ultrasonic waves) in this condition. Hence, it is possible to favorably clean the second major surface of the substrate while suppressing damage upon the pattern.

The invention is preferably applied to a substrate cleaning technique for cleaning a substrate that has a first major surface on which a pattern is formed and a second major surface to be cleaned.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate cleaning method of cleaning a substrate that has a first major surface on which a pattern is formed and a second major surface to be cleaned, the method comprising:
a liquid film forming step of supplying first liquid to the first major surface of the substrate so as to form a first liquid film with the first liquid; and
a cleaning step of cleaning the second major surface by providing the second major surface of the substrate with ultrasonic wave-applied liquid, which is obtained by applying ultrasonic waves to second liquid, in a condition that the first liquid film is formed on the first major surface,
wherein the first liquid has a lower cavitation intensity than the cavitation intensity of the second liquid, the cavitation intensity being stress per unit area which acts upon the substrate due to cavitations which are created during propagation of ultrasonic waves to liquid.

2. The substrate cleaning method according to claim 1, wherein the first liquid used at the liquid film forming step is liquid which has the same composition as that of the second liquid and has a lower gas concentration than that of the second liquid.

3. The substrate cleaning method according to claim 2, wherein the liquid film forming step includes a step of degassing the first liquid and lowering the cavitation intensity of the first liquid before supplying the first liquid to the first major surface.

4. The substrate cleaning method according to claim 1, wherein both of the first liquid and the second liquid are water, carbonated water or hydrogen water.

5. The substrate cleaning method according to claim 1, wherein at the liquid film forming step, liquid which has a different composition than that of the second liquid is used as the first liquid.

6. The substrate cleaning method according to claim 5, wherein the first liquid has a larger coefficient of cavitation than that of the second liquid and a smaller bubble collapsing energy than that of the second liquid.

7. The substrate cleaning method according to claim 5, wherein the first liquid is isopropyl alcohol or mixture which is obtained by mixing water with isopropyl alcohol while the second liquid is water, carbonated water or hydrogen water.

8. The substrate cleaning method according to claim 1, wherein the cleaning step includes a step of dissolving inactive gas or carbonated gas in the second liquid prior to application of ultrasonic waves to the second liquid, accordingly increasing the gas concentration in the second liquid and thereby increasing the cavitation intensity of the second liquid.

9. The substrate cleaning method according to claim 1, wherein the liquid film forming step and the cleaning step are executed while rotating the substrate about the center of rotation.

10. The substrate cleaning method according to claim 9, wherein the cleaning step includes a step of supplying the ultrasonic wave-applied liquid to the second major surface from outside the substrate along the radial direction of the substrate in the condition that the second liquid is supplied to the second major surface of the substrate and a second liquid film is formed.

11. The substrate cleaning method according to claim 1, wherein the cleaning step includes a step of continuously applying ultrasonic waves to the second liquid and creating the ultrasonic wave-applied liquid.

12. The substrate cleaning method according to claim 1, wherein the cleaning step includes a step of alternately repeating application and discontinuation of application of ultrasonic waves to the second liquid and creating the ultrasonic wave-applied liquid.

13. A substrate cleaning apparatus for cleaning a substrate that has a first major surface on which a pattern is formed and a second major surface to be cleaned, the apparatus comprising:
a liquid film former that supplies first liquid to the first major surface of the substrate so as to form a first liquid film with the first liquid; and
a nozzle that ejects second liquid toward the second major surface of the substrate in the condition that the first liquid film is formed on the first major surface;
a vibrator that is disposed to the nozzle; and
an oscillator that outputs an oscillation signal to the vibrator and makes the vibrator apply ultrasonic waves to the second liquid,
wherein the liquid film former uses, as the first liquid, liquid which has a lower cavitation intensity than the cavitation intensity of the second liquid, the cavitation intensity being stress per unit area which acts upon the substrate due to cavitations which are created during propagation of ultrasonic waves to liquid.

14. The substrate cleaning apparatus according to claim 13, wherein the liquid film former comprises: a degasser that degasses the first liquid; and an ejector that ejects the first liquid degassed by the degasser toward the first major surface of the substrate.

15. The substrate cleaning apparatus according to claim 13, comprising a gas concentration adjust mechanism that dissolves inactive gas or carbonated gas in the second liquid and accordingly increases the gas concentration in the second liquid,
wherein the vibrator applies ultrasonic waves to the second liquid whose gas concentration is increased by the gas concentration adjust mechanism.
